(19) United States
(12) Patent Application Publication
(10) Pub. No.: US 2024/0241447 A1
(43) Pub. Date: Jul. 18, 2024

(54) RESIST STRIPPER COMPOSITION AND PATTERN FORMATION METHOD USING SAME

(71) Applicant: DONGWOO FINE-CHEM CO., LTD., Jeollabuk-do (KR)

(72) Inventors: SUNG SIK KIM, Jeollabuk-do (KR); HAN BYEOL KANG, Gyeonggi-do (KR); JEONG HYUN KIM, Jeollabuk-do (KR); SOON HONG PANG, Jeollabuk-do (KR); HYUNG JIN CHO, Jeollabuk-do (KR)

(21) Appl. No.: 18/436,247

(22) Filed: Feb. 8, 2024

Related U.S. Application Data
(63) Continuation of application No. PCT/KR2022/011069, filed on Jul. 27, 2022.

(30) Foreign Application Priority Data
Aug. 11, 2021 (KR) 10-2021-0106146
Jul. 22, 2022 (KR) 10-2022-0090791

(51) Int. Cl. G03F 7/42; G03F 7/00; H01L 21/768

(52) U.S. Cl. CPC G03F 7/425; G03F 7/0035; H01L 21/768

(57) ABSTRACT

A resist stripper composition according to an embodiment includes an alkali compound including an ammonium hydroxide-based compound, ethanol, and a polar organic solvent, which includes a sulfoxide-based compound. In a pattern formation method according to an embodiment, a photoresist pattern is formed on a substrate, a conductive pattern using the photoresist pattern is formed, and the photoresist pattern is removed by using the resist stripper composition. A resist stripper having an improved stripping rate and resist solubility is provided.

### PRIORITY

The present application is a continuation application to International Application No. PCT/KR2022/011069 with an International Filing Date of Jul. 27, 2022, which claims the benefit of Korean Patent Application Nos. 10-2021-0106146 filed on Aug. 11, 2021 and 10-2022-0090791 filed on Jul. 22, 2022 at the Korean Intellectual Property Office, the disclosures of which are incorporated by reference herein in their entirety.

### BACKGROUND

### 1. Technical Field

The present invention relates to a resist stripper composition and a pattern formation method using the same. More particularly, the present invention relates to a resist stripper composition containing a stripping compound and a solvent, and a pattern formation method using the same.

### 2. Background Art

A process of using a photoresist is performed in a semiconductor fabrication process and a panel process of a display device. For example, a photoresist layer may be formed on a substrate, and the photoresist layer may be exposed and developed to form a photoresist pattern.

The photoresist pattern may be used as various mask patterns such as an etching mask, a wiring forming mask, an ion implantation process mask, etc. After the above-described process is performed, the photoresist pattern or the mask pattern may be removed through a strip process and/or an ashing process.

For example, the photoresist pattern can be peeled off by supplying or spraying a strip solution containing a compound with stripping properties on the photoresist pattern.

To enhance stripping efficiency of the photoresist pattern, the strip solution having a sufficient solubility for a polymer material contained in the photoresist is preferable.

If the solubility of the strip solution is insufficient, a stripped photoresist residue may remain on the substrate, thereby degrading a reliability of the semiconductor device or the display device and causing product defects.

For example, Korean Published Patent Application No. 10-2016-0033855 discloses a resist stripping composition containing an alkanol amine, but as described above, which may cause resist residues due to lack of solubility.

### SUMMARY

According to an aspect of the present invention, there is provided a resist stripper composition having improved stripping efficiency and reliability.

According to an aspect of the present invention, there is provided a pattern formation method using the stripper composition.

1. A resist stripper composition, including: an alkaline compound including an ammonium hydroxide-based compound; ethanol; and a polar organic solvent containing a sulfoxide-based compound.

2. The resist stripper composition according to the above 1, wherein the polar organic solvent includes dimethyl sulfoxide.

3. The resist stripper composition according to the above 1, wherein the alkaline compound further includes an amine-based compound.

4. The resist stripper composition according to the above 3, wherein the amine-based compound includes an alkoxy alkyl amine.

5. The resist stripper composition according to the above 1, including 0.1 to 5 wt % of the ammonium hydroxide-based compound; 4 to 40 wt % of ethanol; and 55 to 95 wt % of the polar organic solvent.

6. The resist stripper composition of the above 5, further including 0.1 to 5 wt % of a deionized water based on the total weight of the resist stripper composition.

7. The resist stripper composition according to the above 6, wherein a difference between a content of the ammonium hydroxide-based compound and a content of the deionized water is 2 wt % or less.

8.A pattern formation method, including: forming a photoresist pattern on a substrate; forming a conductive pattern using the photoresist pattern; and removing the photoresist pattern using the resist stripper composition according to the above-described embodiments.

9. The pattern formation method to the above 8, wherein removing the photoresist pattern includes removing the photoresist pattern from a lower portion thereof using the resist stripper composition.

10. The pattern formation method according to the above 9, wherein the photoresist pattern includes a first photoresist pattern and a second photoresist pattern sequentially formed from the substrate, wherein the first photoresist pattern is removed in advance using the resist stripper composition.

11. The pattern formation method according to the above 8, further including forming a conductive layer on the substrate before forming the photoresist pattern.

12. The pattern formation method of the above 8, wherein a plurality of the photoresist patterns are formed, and forming the conductive pattern including filling a space between the adjacent photoresist patterns with a conductive material.

According to embodiments of the present invention, a resist stripper composition may include an alkali compound, ethanol and a polar organic solvent. Ethanol has improved solubility in both the alkaline compound and photoresist components. Accordingly, striped photoresist components may be dissolved and removed while increasing a photoresist strip efficiency by a contact with the alkali compound and the photoresist. Therefore, generation of a photoresist residue maybe prevented after the strip process, and a strip rate/efficiency may be improved.

In some embodiments, the stripper composition may include dimethyl sulfoxide as the polar organic solvent, and may effectively promote swelling of the photoresist, thereby further enhancing the strip rate/efficiency.

### BRIEF DESCRIPTION OF THE DRAWINGS

FIGS. 1 to 5 are schematic cross-sectional views illustrating a pattern formation method in accordance with example embodiments.

### DETAILED DESCRIPTION OF THE EMBODIMENTS

Embodiments of the present invention provide a resist stripper composition including an alkaline compound, ethanol and a polar organic solvent and providing improved strip efficiency and reliability. Additionally, a pattern formation method using the resist stripper composition is provided.

Hereinafter, embodiments of the present invention will be described in more detail with reference to experimental examples and drawings. However, since the embodiments provided in the present specification provide some preferred examples and serve to further understand the technical concepts of the present invention together with the above-described contents of the present invention, the present invention should not be interpreted by being limited to the matters described in such embodiments.

### <Resist Stripper Composition>

A resist stripper composition (hereinafter, that may be abbreviated as a stripper composition) according to exemplary embodiments may include an alkaline compound, ethanol and a polar organic solvent.

### Alkaline Compound

The alkaline compound may be used as a compound having etching or stripping properties for a photoresist pattern cured by exposure and development processes. In example embodiments, the alkaline compound may be included as a main stripping agent in the stripper composition.

For example, intramolecular or intermolecular bonds in a negative-type resist resin cured may be cleaved by the alkaline compound. Additionally, a resist residue remaining on a substrate or a wafer after a stripping process may be removed by the alkaline compound.

In example embodiments, the alkaline compound may include an ammonium hydroxide-based compound. For example, the alkaline compound may include tetramethylammonium hydroxide, tetraethylammonium hydroxide, tetrapropylammonium hydroxide, tetrabutylammonium hydroxide, ethyltrimethylammonium hydroxide, tris(2-hydroxyethyl) methylammonium hydroxide, benzyltrimethyl ammonium hydroxide, etc. These may be used alone or in a combination of two or more therefrom.

In some embodiments, the alkaline compound may further include an amine-based compound. The amine-based compound may be included as an auxiliary stripping agent to further improve a stripping rate or efficiency.

For example, the amine-based compound may include a primary amine, a secondary amine or a tertiary amine. In one embodiment, an alkoxy amine or an alkoxy alkyl amine, preferably an alkoxy alkyl amine may be used as the amine-based compound. In this case, compatibility with the ammonium hydroxide-based compound and solubility of the resist residue may be improved.

Non-limiting examples of the alkoxy alkyl amine may include 3-methoxypropyl amine, 3-butoxypropyl amine, 3-ethoxypropylamine, bis(2-methoxyethyl)amine, etc.

In one embodiment, the alkaline compound or the amine-based compound may not include a hydroxyl group-containing amine (e.g., an alkanol amine or a hydroxyl amine). The hydroxyl group-containing amine may inhibit stripping properties of the ammonium hydroxide-based compound and may reduce a dissolving capability of the stripper composition for the resist residue. Additionally, a metal pattern (e.g., a copper wiring) may be oxidized or corroded during the stripping process, thereby deteriorating a process reliability.

In some embodiments, a content of the ammonium hydroxide-based compound based on a total weight of the stripper composition may be from about 0.1 to 5 wt %. Within the above range, corrosion of the metal pattern may be suppressed while providing sufficient the stripping capability for the resist resin.

Preferably, the content of the ammonium hydroxide-based compound may be from about 0.3 to 5 wt %.

If the amine-based compound is included, a content of the amine-based compound based on the total weight of the stripper composition may be from about 1 to 40 wt %, preferably from about 5 to 30 wt %.

### Ethanol

In example embodiments, the stripper composition may include ethanol, and ethanol may serve as a carrier or a co-solvent for the ammonium hydroxide-based compound. Additionally, ethanol may be absorbed into a negative resist pattern to induce a swelling of the resist pattern. Accordingly, penetration of the ammonium hydroxide-based compound into the resist pattern may be promoted, thereby improving the stripping rate and efficiency.

In some embodiments, the stripper composition may not contain an alcohol having 3 or more carbon atoms (an alcohol represented by ROH, where R is an alkyl group having 3 or more carbon atoms). The alcohol having 3 or more carbon atoms may rapidly reduce the dissolving capability of the cured resist pattern to generate the resist residues on the substrate or the wafer, thereby deteriorating an overall reliability of the stripping process.

In some embodiments, the stripper composition may not contain methanol. For example, methanol may be volatilized and removed during the stripping process performed at a temperature of 70° C. or higher. Accordingly, time-dependent stability and reliability of the stripping process may be degraded.

In an embodiment, even though an alcohol other than ethanol (methanol, or ROH where R is an alkyl group having 3 or more carbon atoms) is included, the alcohol may be included in a small amount compared to that of ethanol. For example, the alcohol other than ethanol may be included in an amount of ½ or less based on a weight of ethanol.

In some embodiments, a content of ethanol based on the total weight of the stripper composition may be from about 4 to 40 wt %. Within the range, corrosion of the metal pattern may be prevented while providing sufficient stripping capability to a resist resin.

In a preferable embodiment, the content of ethanol may be from about 10 wt % to 30 wt %

### Solvent

The polar organic solvent may swell the cured resist pattern while dissolving the alkaline compound. In consideration of solubility and swelling properties, the polar organic solvent may include a sulfur-containing organic solvent, and preferably a sulfoxide-based solvent.

In example embodiments, dimethyl sulfoxide (DMSO) may be used as the polar organic solvent in consideration of stripping stability and solubility of the alkaline compound in the high-temperature stripping process performed at a temperature of 60° C. or 70° C. or higher.

In some embodiments, the stripper composition may further include a water-soluble organic solvent, and the water-soluble organic solvent may include a compound different from the polar organic solvent.

The water-soluble organic solvent may be added to improve a solubility of, e.g., a hydrated alkaline compound, and swelling of the resist pattern may be further promoted.

For example, the water-soluble organic solvent may include a glycol-based solvent and/or a lactam-based solvent. Examples of the glycol-based solvent may include ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether, diethylene glycol monomethyl ether, diethylene glycol monoethyl ether, diethylene glycol monopropyl ether, diethylene glycol monobutyl ether (=butyl diglycol), propylene glycol, etc.

Examples of the lactam-based solvent include N-methyl-2-pyrrolidone, N-ethyl-2-pyrrolidone, N-propyl-2-pyrrolidone, N-hydroxymethyl-2-pyrrolidone, N-hydroxyethyl-2-pyrrolidone, etc.

For example, the polar organic solvent may be included in an amount of about 55 to 95 wt % based on the total weight of the stripper composition. Preferably, the content of the polar organic solvent may be from about 60 to 90 wt %. Within this range, sufficient swelling of the resist pattern and solubility of the alkaline compound may be obtained.

If the water-soluble organic solvent is included, a content of the water-soluble organic solvent may be from about 5 to 30 wt % based on the total weight of the stripper composition, preferably from about 10 to 20 wt %.

### Other Additional Ingredients

In some embodiments, the stripper composition may further include a deionized water. For example, the deionized water may form a hydrate of the ammonium hydroxide-based compound, thereby enhancing solubility and dispersion properties of the ammonium hydroxide-based compound.

As described above, the deionized water may be included in an equivalent amount substantially corresponding to the content of the ammonium hydroxide-based compound. In example embodiments, a content of the deionized water may be about 5 wt % or less, e.g., from about 0.1 to 5 wt % based on the total weight of the stripper composition.

The deionized water may be modified depending on the content of the ammonium hydroxide-based compound. In one embodiment, a difference between the contents of the deionized water and the ammonium hydroxide-based compound may be 2 wt % or less, preferably 1 wt % or less, more preferably 0.5 wt % or less, and still more preferably 0.1 wt % or less.

In one embodiment, the content of the deionized water may be substantially the same as the content of the ammonium hydroxide-based compound.

In some embodiments, an additive may be included within a range that does not hinder the above-described effects of the stripper composition. Non-limiting examples of the additive include a surfactant and an anti-corrosion agent known in the field of the stripping process. The additive may be included in an amount of less than about 1 wt % based on the total weight of the stripper composition.

According to embodiments of the present invention, a pattern formation method using the above-described stripper composition is provided.

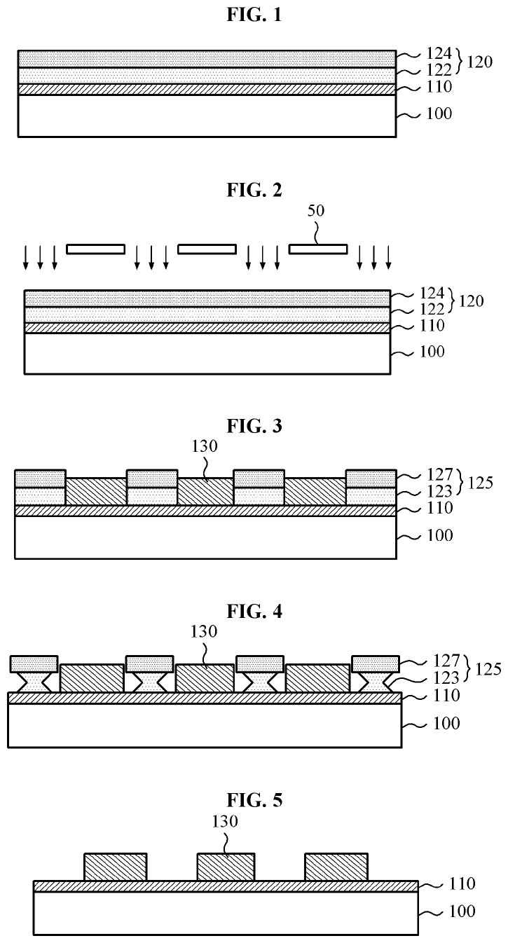

FIGS. 1 to 5 are schematic cross-sectional views illustrating a pattern formation method in accordance with example embodiments.

7Referring to FIG. 1, a photoresist layer 120 may be formed on a substrate 100. The substrate 100 may include, e.g., a semiconductor substrate such as a silicon wafer.

The photoresist layer 120 may be formed by applying and drying, e.g., a negative-type photoresist composition. In some embodiments, a first photoresist film 122 and a second photoresist film 124 may be sequentially formed on the substrate 100 through a plurality of coating processes. Accordingly, the photoresist layer 120 having a thick film structure may be easily formed.

In an embodiment, the first and second photoresist layers 122 and 124 may be substantially integrally formed with each other.

In some embodiments, a conductive layer 110 may be further formed between the photoresist layer 120 and the substrate 100.

Referring to FIG. 2, an exposure process (e.g., a UV exposure) may be performed on the photoresist layer 120 using a mask 50. A portion of the photoresist layer 120 corresponding to an exposed portion may be crosslinked/cured by the exposure process.

Referring to FIG. 3, a non-exposed portion of the photoresist layer 120 may be removed using a developing solution. Accordingly, the exposed portion of the photoresist layer 120 may remain on the substrate 100 or the conductive layer 110, and thus a photoresist pattern 125 may be formed. The photoresist pattern 125 may include a first photoresist pattern 123 and a second photoresist pattern 127 sequentially stacked on the substrate 100 or the conductive layer 110.

Thereafter, a metal material may fill a space from which the non-exposed portion is removed to form a wiring pattern 130. The metal material may be formed by a plating process, or a deposition process such as a sputtering process, a chemical vapor deposition process, an atomic layer deposition process, etc.

Referring to FIG. 4, the photoresist pattern 125 may be removed by supplying or spraying the stripper composition according to the above-described example embodiments.

In example embodiments, stripping or etching may be initiated from a lower portion of the photoresist pattern 125 (e.g., the first photoresist pattern 123) using the stripper composition. As described above, ethanol may be used together with the alkaline compound and the polar organic solvent such as DMSO, so that the alkaline compound may quickly contact the resist pattern without a loss due to volatilization, and removed resist components may be rapidly dissolved.

Therefore, the lower portion of the photoresist pattern 125 may be sufficiently swelled and removed in advance so that a lift-off strip process may be implemented.

Referring to FIG. 5, the photoresist pattern 125 may be substantially removed by continuing the above-described stripping process. The above-described stripper composition may have improved resist solubility, so that the stripping process may be performed without generation of a resist residue on the conductive layer 110 or the wiring pattern 130.

Additionally, the stripping process may be performed in a lift-off manner as described with reference to FIG. 4, so that the photoresist pattern 125 may be removed substantially completely without a residue of a lower photoresist layer.

As described above, the photoresist pattern 125 may serve as a barrier wall for filling a metal wiring. In one embodiment, the photoresist pattern 125 may serve as an etching mask for etching the conductive layer 110. After the etching process using the photoresist pattern 125, the stripping process may be performed as described above.

Hereinafter, preferable examples are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### Examples and Comparative Examples

Stripper compositions according to Examples and Comparative Examples were prepared with components and weight parts shown in Table 1 below.

TABLE 1

| | alkaline compound | | | | | | polar | | water-soluble | | |
|---|---|---|---|---|---|---|---|---|---|---|---|
| | ammonium | | amine-based | | alcohol | | organic solvent | | organic solvent | | DIW |
| | hydroxide | wt | compound | wt | type | wt | type | wt | type | wt | (wt) |
| Example 1 | TMAH | 0.3 | — | — | EtOH | 15 | DMSO | 84.4 | — | — | 0.3 |
| Example 2 | TMAH | 0.5 | — | — | EtOH | 15 | DMSO | 84 | — | — | 0.5 |
| Example 3 | TMAH | 1.0 | — | — | EtOH | 15 | DMSO | 83 | — | — | 1.0 |
| Example 4 | TMAH | 1.0 | — | — | EtOH | 15 | DPSO | 83 | — | — | 1.0 |
| Example 5 | TMAH | 2.0 | — | — | EtOH | 15 | DMSO | 81 | — | — | 2.0 |
| Example 6 | TMAH | 5.0 | — | — | EtOH | 15 | DMSO | 75 | — | — | 5.0 |
| Example 7 | TMAH | 0.7 | — | — | EtOH | 1 | DMSO | 97.6 | — | — | 0.7 |
| Example 8 | TMAH | 0.7 | — | — | EtOH | 4 | DMSO | 94.6 | — | — | 0.7 |
| Example 9 | TMAH | 0.7 | — | — | EtOH | 10 | DMSO | 88.6 | — | — | 0.7 |
| Example 10 | TMAH | 0.7 | — | — | EtOH | 30 | DMSO | 68.6 | — | — | 0.7 |
| Example 11 | TMAH | 0.7 | — | — | EtOH | 40 | DMSO | 58.6 | — | — | 0.7 |
| Example 12 | TMAH | 0.7 | — | — | EtOH | 45 | DMSO | 53.6 | — | — | 0.7 |
| Example 13 | ETMAH | 1 | — | — | EtOH | 20 | DMSO | 75 | — | — | 4 |
| Example 14 | BTMAH | 2 | — | — | EtOH | 20 | DMSO | 75 | — | — | 3 |
| Example 15 | THEMAH | 2 | — | — | EtOH | 20 | DMSO | 76.5 | — | — | 1.5 |
| Example 16 | TMAH | 0.7 | MOPA | 1 | EtOH | 10 | DMSO | 87.6 | — | — | 0.7 |
| Example 17 | TMAH | 0.7 | MOPA | 5 | EtOH | 10 | DMSO | 83.6 | — | — | 0.7 |
| Example 18 | TMAH | 0.7 | MOPA | 30 | EtOH | 10 | DMSO | 58.6 | — | — | 0.7 |
| Example 19 | TMAH | 0.7 | MOPA | 40 | EtOH | 10 | DMSO | 48.6 | — | — | 0.7 |
| Example 20 | TMAH | 0.7 | MOPA | 45 | EtOH | 10 | DMSO | 43.6 | — | — | 0.7 |
| Example 21 | TMAH | 0.7 | BOPA | 15 | EtOH | 10 | DMSO | 73.6 | — | — | 0.7 |
| Example 22 | TMAH | 0.7 | BMEA | 15 | EtOH | 10 | DMSO | 73.6 | — | — | 0.7 |
| Example 23 | TMAH | 0.7 | — | — | EtOH | 30 | DMSO | 63.6 | — | — | 5.7 |
| Example 24 | TMAH | 1.0 | HA | 5 | EtOH | 15 | DMSO | 73 | — | — | 6.0 |
| Example 25 | TMAH | 1.0 | MEA | 10 | EtOH | 15 | DMSO | 73 | — | — | 1.0 |
| Example 26 | TMAH | 1.0 | AEEA | 10 | EtOH | 15 | DMSO | 73 | — | — | 1.0 |
| Example 27 | TMAH | 1.0 | PDA | 10 | EtOH | 15 | DMSO | 73 | — | — | 1.0 |
| Example 28 | TMAH | 1.0 | TPA | 10 | EtOH | 15 | DMSO | 73 | — | — | 1.0 |
| Comparative | TMAH | 2.0 | — | — | — | — | DMSO | 96 | — | — | 2.0 |
| Example 1 | | | | | | | | | | | |
| Comparative | — | — | MOPA | 30 | EtOH | 20 | DMSO | 50 | — | — | — |
| Example 2 | | | | | | | | | | | |
| Comparative | TMAH | 2.0 | MOPA | 15 | — | — | DMSO | 81 | — | — | 2.0 |
| Example 3 | | | | | | | | | | | |
| Comparative | TMAH | 2.0 | — | — | MeOH | 15 | DMSO | 81 | — | — | 2.0 |
| Example 4 | | | | | | | | | | | |
| Comparative | TMAH | 2.0 | — | — | IPA | 15 | DMSO | 81 | — | — | 2.0 |
| Example 5 | | | | | | | | | | | |
| Comparative | TMAH | 2.0 | — | — | BA | 15 | DMSO | 81 | — | — | 2.0 |
| Example 6 | | | | | | | | | | | |
| Comparative | TMAH | 2.0 | — | — | — | — | DMSO | 66 | NMP/PG | 20/10 | 2.0 |
| Example 7 | | | | | | | | | | | |
| Comparative | TMAH | 2.0 | — | — | — | — | DMSO | 86 | PG | 10 | 2.0 |
| Example 8 | | | | | | | | | | | |
| Comparative | TMAH | 2.0 | MEA | 30 | — | — | DMSO | 66 | — | — | 2.0 |
| Example 9 | | | | | | | | | | | |
| Comparative | TMAH | 2.0 | — | — | EtOH | 15 | | | NMP/PG | 71/10 | 2.0 |
| Example 10 | | | | | | | | | | | |

The compounds listed in Table 1 are as follows.
TMAH: tetramethylammonium hydroxide,
ETMAH: ethyl trimethylammonium hydroxide,
BTMAH: benzyl trimethylammonium hydroxide
THEMAH: tris(2-hydroxyethyl)methylammonium hydroxide,
MOPA: 3-methoxypropylamine
BOPA: 3-butoxypropylamine
BMEA: bis(2-methoxyethyl)amine
EtOH: ethanol
MeOH: methanol
IPA: isopropyl alcohol
IBA: isobutyl alcohol
DMSO: dimethyl sulfoxide
DPSO: diphenyl sulfoxide
NMP: N-methyl-2-pyrrolidone
PG: propylene glycol
HA: hydroxylamine
MEA: monoethanolamine
AEEA: N-(2-aminoethyl)ethanolamine
PDA: propylene diamine
TPA: tripropylamine

### Experimental Example 1

### 1) Evaluation on Resist Stripping Force

A copper layer was formed on a silicon wafer by a physical vapor deposition (PVD) process. A negative-type photoresist layer was double-coated on the copper layer as described with reference to FIG. 2 to form a resist layer having a total thickness of 250 m. After UV curing and developing processes, a copper pattern was formed at a non-exposed area from which the photoresist layer was removed through an electroplating to prepare a test sample.

The prepared sample was cut into 3 cm×3 cm, and the stripper compositions of Examples and Comparative Examples were maintained at a constant temperature of 70° C., the sample was immersed therein, and the composition was stirred at 300 rpm to evaluate a stripping capability according to the following criteria.

### <Criteria for Evaluating Stripping Capability>

⊚: the resist stripping time was less than 10 minutes
O: the resist stripping time was 10 minutes or more and less than 15 minutes
Δ: the resist stripping time was 15 minutes or more and less than 20 minutes
X: the resist stripping time was 20 minutes or more

### 2) Evaluation on Resist Solubility

The samples prepared in the stripping capability evaluation were immersed in the stripper compositions of Examples and Comparative Examples which were constantly maintained at a temperature of 70° C., and stirred at 300 rpm for 15 minutes. After filtering a remaining amount of the resist in the solution through a filter paper, the presence/absence of a resist residue on the filter paper was checked with a naked eye and an optical microscope. A solubility was evaluated according to the following criteria.

### <Criteria for Evaluating Solubility>

O: no residue was observed visually and with the optical microscope.
Δ: the residue was not visually observed, but observed with the optical microscope.
X: the residue was visually observed

### 3) Evaluation on Metal Corrosion

The samples prepared in the stripping capability evaluation were immersed in the stripper compositions of Examples and Comparative Examples, which were constantly maintained at a temperature of 70° C., for 30 minutes. Thereafter, corrosion of the surfaces of the PVD copper layer and the electroplated copper pattern was evaluated using a scanning electron microscope (SEM, Hitachi 5-4700) based on the following criteria.

### <Criteria for Evaluating Metal Corrosion>

©: No surface corrosion observed
O: Some microscopic corrosions were observed
Δ: Local corrosions were observed
X: corrosions were observed throughout the entire surface

The evaluation results are shown in Table 2 below.

TABLE 2

| | | | PVD | electro- |
|---|---|---|---|---|
| | stripping | | deposited | plated |
| | capability | solubility | copper | copper |
| Example 1 | ◯ | Δ | ⊚ | ⊚ |
| Example 2 | ◯ | Δ | ⊚ | ⊚ |
| Example 3 | ⊚ | ◯ | ⊚ | ⊚ |
| Example 4 | ◯ | ◯ | ⊚ | ⊚ |
| Example 5 | ⊚ | ◯ | ◯ | ⊚ |
| Example 6 | ⊚ | ◯ | ◯ | ⊚ |
| Example 7 | Δ | Δ | ◯ | ◯ |
| Example 8 | ◯ | Δ | ⊚ | ⊚ |
| Example 9 | ◯ | ◯ | ⊚ | ⊚ |
| Example 10 | ◯ | ◯ | ⊚ | ⊚ |
| Example 11 | ◯ | Δ | ⊚ | ⊚ |
| Example 12 | Δ | Δ | ⊚ | ⊚ |
| Example 13 | ◯ | ◯ | ◯ | ◯ |
| Example 14 | ⊚ | ◯ | ⊚ | ⊚ |
| Example 15 | ◯ | ◯ | ⊚ | ⊚ |
| Example 16 | ◯ | ◯ | ⊚ | ⊚ |
| Example 17 | ⊚ | ◯ | ⊚ | ⊚ |
| Example 18 | ⊚ | ◯ | ⊚ | ⊚ |
| Example 19 | ⊚ | ◯ | ◯ | ⊚ |
| Example 20 | ⊚ | ◯ | ◯ | ◯ |
| Example 21 | ⊚ | ◯ | ⊚ | ⊚ |
| Example 22 | ⊚ | ◯ | Δ | ◯ |
| Example 23 | ⊚ | ◯ | Δ | Δ |
| Example 24 | ⊚ | ◯ | Δ | Δ |
| Example 25 | ⊚ | ◯ | Δ | Δ |
| Example 26 | ⊚ | ◯ | Δ | Δ |
| Example 27 | ⊚ | ◯ | Δ | Δ |
| Example 28 | ⊚ | ◯ | Δ | Δ |
| Comparative | X | X | ◯ | ⊚ |
| Example 1 | | | | |
| Comparative | X | X | Δ | ⊚ |
| Example 2 | | | | |
| Comparative | X | X | ⊚ | ⊚ |
| Example 3 | | | | |
| Comparative | ⊚ | ◯ | ⊚ | ⊚ |
| Example 4 | | | | |
| Comparative | Δ | X | ⊚ | ⊚ |
| Example 5 | | | | |
| Comparative | X | X | ⊚ | ⊚ |
| Example 6 | | | | |
| Comparative | Δ | X | ⊚ | ⊚ |
| Example 7 | | | | |
| Comparative | Δ | X | ⊚ | ⊚ |
| Example 8 | | | | |
| Comparative | Δ | X | X | Δ |
| Example 9 | | | | |
| Comparative | Δ | X | ⊚ | ⊚ |
| Example 10 | | | | |

Referring to Table 1, the compositions of Examples 1 to 15 included the ammonium hydroxide-based compound, ethanol and DMSO in predetermined amounts and provided improved stripper rate, resist solubility and anti-corrosion properties.

The compositions of Examples 16 to 22 further included the amine-based compound devoid of a hydroxyl group, and entirely provided improved stripping rates without a reduction of the resist solubility.

Referring to Comparative Examples, the compositions without the ammonium hydroxide or ethanol provided remarkably lower stripping rates and resist solubilities than those from Examples.

In Comparative Examples 5 and 6, the alcohols having 3 or more carbon atoms were used, resulting in the reduction of the stripping rate and re-adsorption of the residual resist due to insufficient solubility of the resist.

In Comparative Examples 7 and 8, the alcohol was omitted and a glycol-based solvent was added, but stripping was performed from an upper portion of the resist. Accordingly, re-adsorption of the residual resist occurred.

In Comparative Example 9, the alkaline compound containing a hydroxy group was added, but re-adsorption of the residual resist occurred due to the reduction of the stripping rate and insufficient solubility of the resist.

In Comparative Example 10, the sulfoxide-based polar organic solvent was omitted and the resist solubility was degraded.

### Experimental Example 2: Evaluation on Retention of Stripping Capability

After preparing the stripper compositions of Example 5, Example 18 and Comparative Example 4, a temperature was increased to 65° C. and 70° C., the compositions were stored for 1, 2, and 3 hours, and the resist stripping capability and solubility were evaluated as described above.

The evaluation results are shown in Table 3 and Table 4 below.

TABLE 3

| | 65° C. stripping force stability | | | | | |
|---|---|---|---|---|---|---|
| | 1 hour | | 2 hours | | 3 hours | |
| | stripping | solu- | stripping | solu- | stripping | solu- |
| | capability | bility | capability | bility | capability | bility |
| Example 5 | ⊚ | ◯ | ⊚ | ◯ | ⊚ | ◯ |
| Example 18 | ⊚ | ◯ | ⊚ | ◯ | ⊚ | ◯ |
| Comparative | ◯ | ◯ | ◯ | X | X | X |
| Example 4 | | | | | | |

TABLE 4

| | 70° C. stripping force stability | | | | | |
|---|---|---|---|---|---|---|
| | 1 hour | | 2 hours | | 3 hours | |
| | stripping | solu- | stripping | solu- | stripping | solu- |
| | capability | bility | capability | bility | capability | bility |
| Example 5 | ⊚ | ◯ | ⊚ | ◯ | ◯ | Δ |
| Example 18 | ⊚ | ◯ | ⊚ | ◯ | ◯ | Δ |
| Comparative | ◯ | X | X | X | X | X |
| Example 4 | | | | | | |

Referring to Table 3 and Table 4, in Comparative Example 4 where methanol was used, initial stripping force and solubility were maintained, but the stripping force and solubility rapidly decreased over time by a volatilization under high-temperature process conditions.

What is claimed is:

1. A resist stripper composition comprising:
an alkaline compound including an ammonium hydroxide-based compound;
ethanol; and
a polar organic solvent containing a sulfoxide-based compound.

2. The resist stripper composition according to claim 1, wherein the polar organic solvent includes dimethyl sulfoxide.

3. The resist stripper composition according to claim 1, wherein the alkaline compound further includes an amine-based compound.

4. The resist stripper composition according to claim 3, wherein the amine-based compound includes an alkoxy alkyl amine.

5. The resist stripper composition according to claim 1, comprising,
0.1 to 5 wt % of the ammonium hydroxide-based compound;
4 to 40 wt % of ethanol; and
55 to 95 wt % of the polar organic solvent, based on a total weight of the resist stripper composition.

6. The resist stripper composition of claim 5, further comprising 0.1 to 5 wt % of a deionized water based on the total weight of the resist stripper composition.

7. The resist stripper composition according to claim 6, wherein a difference between a content of the ammonium hydroxide-based compound and a content of the deionized water is 2 wt % or less.

8. A pattern formation method comprising:
forming a photoresist pattern on a substrate;
forming a conductive pattern using the photoresist pattern; and
removing the photoresist pattern using the resist stripper composition according to claim 1.

9. The pattern formation method to claim 8, wherein the removing of the photoresist pattern comprises removing the photoresist pattern from a lower portion thereof using the resist stripper composition.

10. The pattern formation method according to claim 9, wherein the photoresist pattern includes a first photoresist pattern and a second photoresist pattern sequentially formed from the substrate,
wherein the first photoresist pattern is removed in advance using the resist stripper composition.

11. The pattern formation method according to claim 8, further comprising forming a conductive layer on the substrate before forming the photoresist pattern.

12. The pattern formation method of claim 8, wherein a plurality of the photoresist patterns are formed, and the forming of the conductive pattern comprises filling a space between the adjacent photoresist patterns with a conductive material.
